(19) United States
(12) Patent Application Publication
(10) Pub. No.: US 2017/0088941 A1
(43) Pub. Date: Mar. 30, 2017

(54) APPARATUS FOR PROCESSING OF A MATERIAL ON A SUBSTRATE AND METHOD FOR MEASURING OPTICAL PROPERTIES OF A MATERIAL PROCESSED ON A SUBSTRATE

(71) Applicant: Applied Materials, Inc., Santa Clara, CA (US)

(72) Inventors: Jüergen SCHROEDER, Grosskrotzenburg (DE); Hans-Georg LOTZ, Gründau-Rothenbergen (DE)

(21) Appl. No.: 15/311,486

(22) PCT Filed: May 16, 2014
(86) PCT No.: PCT/EP2014/060136

§ 371 Date: Nov. 15, 2016

(51) Int. Cl. C23C 14/54; C23C 16/52; C23C 16/50; G01N 21/89; G01N 21/47; G01N 21/55; G01N 21/59; C23C 16/54; C23C 16/458

(52) U.S. Cl. CPC C23C 14/547; C23C 16/545; C23C 16/52; C23C 16/50; C23C 16/458; G01N 21/474; G01N 21/55; G01N 21/59; G01N 21/8901; G01N 2201/12746

(57) ABSTRACT

According to one aspect of the present disclosure an apparatus for processing of a material on a substrate is provided. The apparatus includes a vacuum chamber and a measuring arrangement configured for measuring one or more optical properties of the substrate and/or the material processed on the substrate, the measuring arrangement including at least one sphere structure located in the vacuum chamber.

### TECHNICAL FIELD

Embodiments of the present disclosure relate to an apparatus for processing of a material on a substrate and a method for measuring one or more optical properties of a material processed on a substrate by means of a processing apparatus. Embodiments of the present disclosure particularly relate to an apparatus for processing a substrate and measuring one or more optical properties of a material processed on the substrate.

### BACKGROUND

Optical coatings on substrates such as plastic films can be characterized by specified spectral reflectance and transmittance values and resulting color values. A reliable inline measurement of transmission and reflection (T/R) during production of the coatings can be an aspect that needs to be considered for the control of the depositions process and the optical quality control of the coated product. The more sophisticated part of the T/R measurement is the measurement of the reflectance. The reflectance measurement can be challenging on moving plastic films since small deviations in flatness of the film cause geometrical changes in the path of the reflected beam to the detector, resulting in erroneous measurement results. In deposition apparatuses, reflectance can be measured in positions where the plastic film is in mechanical contact with guide rollers of the apparatus to ensure a flat contact of the plastic film with the surface of the roller.

However, the incident light beam is not only reflected on the front and back surfaces of the plastic film, but also on the surface of the guide roller with which the plastic film is in contact. Since the reflectance of, for instance metallic, guide rollers is rather high (e.g., R>50%), a roller surface with low or reduced reflectance is beneficial. The guide roller can have a black or blackened surface providing the low or reduced reflectance. However, the reflectance of these black or blackened surfaces particularly suffers from inhomogeneous reflectance. The reliability of the absolute reflectance is rather low. Furthermore, this measuring method is restricted to fixed measuring device positions along the film width. For cost reasons the number of fixed measuring devices or measuring heads in roll-to-roll (R2R) sputter machines can be limited between one and five. Even systems with five measuring devices do not deliver sufficient information about layer uniformity and compliance with the optical specification along the substrate width.

Therefore, there remains a need for apparatuses with which improved quality inspection of substrates can be achieved. There is also a need for improved methods of measuring optical properties of substrates and/or material processed on the substrate, particularly suitable for processing systems with high output capacity.

### SUMMARY

In light of the above, an apparatus for processing of a material on a substrate and a method for measuring one or more optical properties of a substrate and/or a material processed on the substrate by means of a processing apparatus are provided. Further aspects, benefits, and features of the present disclosure are apparent from the claims, the description, and the accompanying drawings.

According to one aspect of the present disclosure an apparatus for processing of a material on a substrate is provided. The apparatus includes a vacuum chamber and a measuring arrangement configured for measuring one or more optical properties of the substrate and/or the material processed on the substrate, the measuring arrangement including at least one sphere structure located in the vacuum chamber.

According to another aspect of the present disclosure an apparatus for processing of a material on a substrate is provided. The apparatus includes a vacuum chamber, a measuring arrangement configured for measuring at least one of a reflectance and a transmission of the substrate and/or the material processed on the substrate, the measuring arrangement including at least one sphere structure located in the vacuum chamber, and a transport device configured for moving at least the sphere structure within the vacuum chamber between a measuring position and at least one calibration position.

According to still another aspect of the present disclosure a method for measuring one or more optical properties of a substrate and/or a material processed on the substrate by means of a processing apparatus in provided. The processing apparatus includes a vacuum chamber. The method includes measuring the one or more optical properties using a measuring arrangement having at least one sphere structure located in the vacuum chamber.

The present disclosure is also directed to an apparatus for carrying out the disclosed methods and including apparatus parts for performing each described method steps. These method steps may be performed by way of hardware components, a computer programmed by appropriate software, by any combination of the two or in any other manner. Furthermore, the disclosure is also directed to methods for operating the described apparatus. It includes method steps for carrying out every function of the apparatus.

Further aspects, advantages, and features of the present disclosure are apparent from the dependent claims, the description, and the accompanying drawings.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

Typical embodiments are depicted in the drawings and are detailed in the description which follows. In the drawings:

FIG. 1 shows a schematic perspective view of a reflection and transmission measurement of optical coatings;

FIG. 2 shows a schematic view of a sphere structure of a measuring arrangement according to embodiments described herein;

FIG. 3 shows a schematic view of an apparatus for processing of a material on a substrate according to embodiments described herein;

FIG. 4 shows another schematic view of a part of the apparatus for processing of a material on a substrate of FIG. 3 with the sphere structure being at a measuring position and at two calibration positions within the vacuum chamber;

FIG. 5 shows a schematic view of yet another apparatus for processing of a material on a substrate according to embodiments described herein;

FIG. 6 shows a schematic view of measurement positions for evaluation of a thickness distribution;

FIG. 7 shows another schematic view of measurement positions for evaluation of a thickness distribution; and

FIG. 8 shows a flow chart of a method for measuring one or more optical properties of a substrate and/or a material processed on the substrate by means of a processing apparatus according to embodiments described herein.

### DETAILED DESCRIPTION OF EMBODIMENTS

Reference will now be made in detail to the various embodiments, one or more examples of which are illustrated in each figure. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. Generally, only the differences with respect to the individual embodiments are described. Unless specified otherwise, the description of a part or aspect in one embodiment applies to a corresponding part or aspect in another embodiment as well.

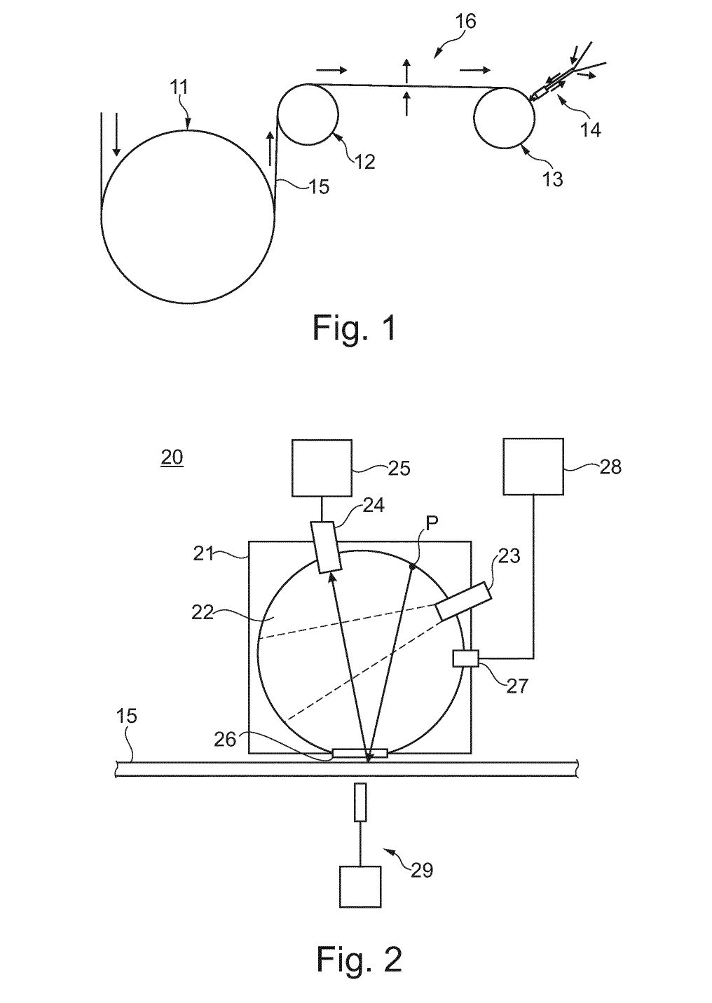

FIG. 1 shows a schematic perspective view of a reflection and transmission measurement of optical coatings.

In deposition apparatuses specular reflectance can be measured in positions where the substrate, e.g. a plastic film, is in mechanical contact with a roller (e.g., a guide roller) of the apparatus to ensure a flat contact of the plastic film with the surface of the roller, as will be explained in more detail below with reference to FIG. 1.

As shown in FIG. 1, a substrate 15 is carried and conveyed by a coating drum 11, a first roller 12 and/or a second roller 13. The first roller 12 and the second roller 13 can be guide rollers. In a position between the first roller 12 and the second roller 13 a transmission measurement device 16 is provided. The position or area between the first roller 12 and the second roller 13 may also be referred to as “free span” or “free span position”. Further, at another position where the substrate 15, e.g. a plastic film, is in mechanical contact with the second roller 13, a reflectance measurement device 14 is provided.

However, the incident light beam is not only reflected on the front and back surfaces of the substrate 15, but also on the surface of the second roller 13. Since the reflectance R of for instance metallic rollers is rather high (e.g., R>50%), a roller surface with low or reduced reflectance is beneficial. The second roller 13 has a black or blackened surface so that the surface of the second roller 13 has the low or reduced reflectance. However, the reflectance of these black or blackened surfaces suffers from insufficient low and inhomogeneous reflectance. The reliability of a measurement of the absolute reflectance is rather low.

The present disclosure provides an apparatus for processing of a material on a substrate and a method for measuring one or more optical properties of a substrate and/or a material processed on the substrate, which use a measuring arrangement having a sphere structure to allow simultaneous reflectance measurements and transmission measurements particularly at the same position, for instance in a free span position of the substrate or plastic film between two rollers. Even if the surface of the film is not flat, the reflected light is almost completely collected in the sphere structure.

The sphere structure provides a uniform scattering or diffusing of light inside the sphere structure. Light incident on an inner surface of the sphere structure is equally distributed within the sphere. Directional effects of the incident light are minimized. This allows the measure the incident light (e.g., light reflected from or transmitted through the substrate and/or the material processed on the substrate) with a high degree of accuracy and reliability.

The term “substrate” as used herein shall particularly embrace flexible substrates such as a plastic film, a web or a foil. However, the present disclosure is not limited thereto and the term “substrate” may also embrace inflexible substrates, e.g., a wafer, slices of transparent crystal such as sapphire or the like, or a glass plate. According to some embodiments, the substrate may be a transparent substrate. The term “transparent” as used herein shall particularly include the capability of a structure to transmit light with relatively low scattering, so that, for example, light transmitted therethrough can be seen in a substantially clearly manner Typically, the substrate includes polyethylene terephthalate (PET).

According to some embodiments, the sphere structure is or includes an integrating sphere. An integrating sphere (or Ulbricht sphere) is an optical device including a hollow spherical cavity having at least one port, e.g. at least one entrance port and/or at least one exit port. An interior of the hollow spherical cavity can be covered with a reflective coating (e.g., a diffuse white reflective coating). The integrating sphere provides a uniform scattering or diffusing of light inside the sphere. Light incident on the inner surface is distributed equally within the sphere. Directional effects of the incident light are minimized. An integrating sphere may be thought of as a diffuser which preserves power but destroys spatial information.

FIG. 2 shows a schematic view of a measuring arrangement 20 with a sphere structure according to embodiments described herein.

The measuring arrangement 20 is arranged within a vacuum chamber (not shown). The vacuum chamber can be or include a process chamber where a substrate 15 to be coated is located. The apparatus according to embodiments described herein can be a deposition apparatus, and particularly a sputtering apparatus, a physical vapor deposition (PVD) apparatus, a chemical vapor deposition (CVD) apparatus, a plasma enhanced chemical vapor deposition (PECVD) apparatus, etc.

As schematically shown in FIG. 2, the measuring arrangement 20 according to embodiments described herein is configured for measuring one or more optical properties of the substrate 15 and/or the material processed on the substrate 15, particularly a reflectance and/or a transmission. The term “reflectance” as used throughout the application refers to the fraction of the total radiant flux incident upon a surface that is reflected. The surface may include at least one of a surface of the material processed on the substrate, a front surface of the substrate and a back surface of the substrate. It is noted that the terms “reflectance” and “reflectivity” can be used synonymously. The term “transmission” as used throughout the application refers to a fraction of incident light (electromagnetic radiation) that passes through the substrate for instance having a material or layers processed thereon. The terms “transmission” and “transmittance” can be used synonymously.

The measuring arrangement 20 includes a sphere structure 21 having a cavity 22. According to some embodiments, the cavity 22 can be a hollow spherical cavity. In typical implementations, a surface of the cavity 22 is at least partially covered with a reflective coating (e.g., a white reflective coating). The sphere structure 21 provides a uniform scattering or diffusing of light inside the sphere structure 21. Light incident on the surface of the cavity 22 is distributed equally within the cavity 22.

According to some embodiments, which could be combined with other embodiments described herein, the sphere structure 21 is or includes an integrating sphere. According to embodiments, which can be combined with other embodiments described herein, the sphere structure 21, and particularly the cavity 22 of the sphere structure 21, has an inner diameter of 150 mm or less, particularly of 100 mm or less, more particularly of 75 mm or less.

For measuring the one or more optical properties, the measuring arrangement may include a configuration with at least one light source and at least one detector. A possible configuration of the at least one light source and the at least one detector is described in the following. However, other configurations are possible.

In typical implementations, the measuring arrangement 20 includes a light source 23. The light source 23 is configured for emitting light into the cavity 22 of the sphere structure 21. According to embodiments, which can be combined with other embodiments described herein, the light source 23 is configured for emitting light in the visible radiation range of 380-780 nm and/or in the infrared radiation range of 780 nm to 3000 nm and/or in the ultraviolet radiation range of 200 nm to 380 nm.

According to embodiments, which can be combined with other embodiments described herein, the light source 23 is arranged such that light can be emitted into the cavity 22. The light source 23 may be arranged within the cavity 22, or attached to an inner wall or surface of the cavity 22. According to embodiments, the light source 23 can be arranged outside the sphere structure 21, wherein the wall of the sphere structure 21 can include an opening which is configured such that light emitted from the light source 23 can shine into the interior of the sphere structure 21, and particularly into the cavity 22.

In some embodiments, the light source 23 can be provided at a position remote from the sphere structure 21. Fiber optics can be used for guiding the light into the sphere structure 21, and particularly into the cavity 22.

According to embodiments, which can be combined with other embodiments described herein, the light source 23 may be configured as, e.g., a filament bulb, a tungsten halogen bulb, LEDs, high-power LEDs or Xe-Arc-Lamps. The light source 23 may be configured such that the light source 23 can be switched on and off for short times. For the purpose of switching, the light source 23 can be connected to a control unit (not shown).

In typical embodiments, the sphere structure 21 has at least one port 26. The port 26 can be configured as entrance port and/or exit port. As an example, light reflected from or transmitted through the substrate 15 and/or the material processed on the substrate 15 can enter the sphere structure 21 through the port 26. In another example, light provided by the light source 23 can exit through the port 26, for instance for a reflectance measurement. The port 26 can be covered with a cover element, for instance a protective glass. In other examples the port 26 can be uncovered or open.

According to embodiments, which can be combined with other embodiments described herein, the port 26 may have a diameter of 25 mm or less, particularly of 15 mm or less, more particularly of 10 mm or less. By increasing the diameter of the port 26, a larger portion of the substrate 15 may be illuminated for conducting a measurement of the at least one optical property of the substrate 15 and/or the material processed on the substrate 15.

In typical implementations, diffuse light emitted from the sphere structure 21 through the port 26 can be shone onto the substrate 15 for measurement of at least one optical property of the substrate 15 and/or the material processed on the substrate 15. By illuminating the substrate 15 with diffuse light, the light shone onto the substrate 15 is of the same intensity throughout an illuminated portion of the substrate 15. According to some embodiments, which can be combined with other embodiments described herein, the emitted diffuse light can be characterized by emitting the light at a plurality of angles, particularly with a uniform angular distribution of the intensity of the light. For example, this can be generated by diffuse reflection in the sphere structure, e.g. an integrating sphere or Ulbricht sphere, where the material in the sphere is selected for providing diffuse reflection.

As exemplarily illustrated in FIG. 2, a beam of light, which is illustrated as a solid line with arrows indicating the direction of the light, may have a position of origin P on the interior surface of the sphere structure 21 before the beam exits the port 26. The beam may be reflected from the substrate 15 and/or the material processed on the substrate 15, as exemplarily shown in FIG. 2, and, in case of reflectance, enter the port 26 with an angle of reflectance.

According to some embodiments, which can be combined with other embodiments described herein, the measuring arrangement 20 includes a first detector at the sphere structure 21 configured for measuring a reflectance of the substrate 15 and/or the material processed on the substrate 15. In typical implementations, the first detector includes a first detecting device 24 and a second detecting device 27.

The first detecting device 24 can be configured for receiving light entering through the port 26 (as indicated by the solid line with arrows indicating the direction of the light), and particularly light reflected from the substrate 15 and/or the material processed on the substrate 15. According to embodiments, which can be combined with other embodiments described herein, the first detecting device 24 is configured and arranged such that no light reflected from the inside of the sphere structure 21 is detected by the first detecting device 24. For example, the first detecting device 24 can be arranged such that only light entering through the port 26 of the sphere structure 21, e.g. due to reflection on the substrate 15 and/or the material processed on the substrate 15, can be detected by the first detecting device 24.

The second detecting device 27 can be configured for receiving light scattered or reflected from the interior wall of the cavity 22. As an example, the second detecting device 27 can provide a reference measurement. In typical implementations the reflectance is determined based on a first light intensity received or measured by the first detecting device 24 and a second light intensity received or measured by the second detecting device 27. The first light intensity may include light reflected from the substrate 15 and/or the material processed on the substrate 15 that directly reaches the first detecting device 24 without being reflected in the interior of the sphere structure 21. The second light intensity may be a reference light intensity that does substantially not include such direct light reflected from the substrate 15 and/or the material processed on the substrate 15.

According to embodiments, which can be combined with other embodiments described herein, the first light detecting device, i.e. a first detecting device 24, and/or the second light detecting device, i.e. a second detecting device 27, are configured and arranged such that no direct light from the light source 23 is detected by the first light detecting device and/or the second light detecting device. For example, screening means (not shown) may be provided within the sphere structure 21, which prevent light emitted by the light source 23 from directly hitting the first light detecting device and/or the second light detecting device. Such screening means may, for example, be realized by shields, apertures or lenses, which are configured and arranged such that no direct light emitted by the light source 23 can hit the first light detecting device and/or the second light detecting device.

According to embodiments, a first data processing or data analysis unit 25 is connected to the first detecting device 24, and a second data processing or data analysis unit 28 is connected to the second detecting device 27. According to embodiments, the first detecting device 24 may be connected to the first data processing or data analysis unit 25 via a cable or wireless connection, and/or the second detecting device 27 may be connected to the second data processing or data analysis unit 28 via a cable or wireless connection.

The data processing or data analysis units 25 and 28 can be adapted to inspect and analyze the signals of the first detecting device 24 and the second detecting device 27, respectively. According to some embodiments, if any characteristic of the substrate 15 and/or the material processed on the substrate 15 is measured which is defined as non-normal, the data processing or data analysis units 25 and 28 may detect the change and trigger a reaction, such as a stop of the processing of the substrate 15.

According to some embodiments, which can be combined with other embodiments described herein, at least one of the connections between the first data processing or data analysis unit 25 and the first detecting device 24, and the second data processing or data analysis unit 28 and the second detecting device 27 can include or be a fiber optic connection. As an example, when the measuring arrangement 20 is moved within the vacuum chamber for instance to change a measuring position, the fiber optic connection does not move, since the data processing or data analysis units 25 and 28 and the detecting devices 24 and 27 are moved simultaneously. This can improve a measurement accuracy, because a light intensity of optical glass fibers can change when the fibers are bent. In some implementations, the optical measurement can be stabilized by an additional measurement of the light source intensity using for instance a reference channel.

According to some embodiments, which can be combined with other embodiments described herein, the measuring arrangement 20 includes a second detector 29 for a transmission measurement of the substrate 15 and/or the material processed on the substrate 15. The second detector 29 can be configured for measuring a transmission, particularly of the substrate 15 and/or the material processed on the substrate 15. In typical implementations, the second detector 29 is connected to a data processing or data analysis unit, as it is described above with reference to the first detector.

The second detector 29 can be configured for receiving light exiting through the port 26, and particularly light transmitted through the substrate 15 and/or the material processed on the substrate 15. According to embodiments, which can be combined with other embodiments described herein, the second detector 29 is arranged outside or opposite the sphere structure 21 with a gap between the second detector 29 and the sphere structure 21. The substrate 15 can be positioned within the gap for measuring transmission, e.g. light transmitted through the substrate 15 and/or the material processed on the substrate 15.

In the above example a configuration of the measuring arrangement with a light source 23, a first detector having a first detecting device 24 and a second detecting device 27, and a second detector 29 is described. However, other configurations are possible. As an example, two sphere structures could be provided, wherein the first sphere structure can be configured for a reflectance measurement, and the second sphere structure can be configured for a transmission measurement. A first light source and a first detector could be provided at the first sphere structure for the reflectance measurement. A second detector configured for receiving light entering through a port of the sphere structure, and particularly light transmitted through the substrate and/or the material processed on the substrate, could be provided at the second sphere structure, and a second light source could be provided outside or opposite the second sphere structure with a gap between the second light source and the second sphere structure. The substrate can be positioned within the gap for measuring transmission, e.g. light transmitted through the substrate and/or the material processed on the substrate.

By providing the measuring arrangement with a first detector and a second detector it is possible to measure both the transmission and the reflectance of the substrate and/or the material processed on the substrate at the same position. More information with respect to the properties of the substrate can be obtained.

The measuring arrangement of the present disclosure provides an improvement of reflectance and/or transmission measurements by using the sphere structure. As an example, reflectance and/or transmission of a flexible substrate such as a plastic film can be measured for instance in a free span position. The measuring arrangement also works when the flexible substrate is not flat, for instance in a case where the flexible substrate has wrinkles.

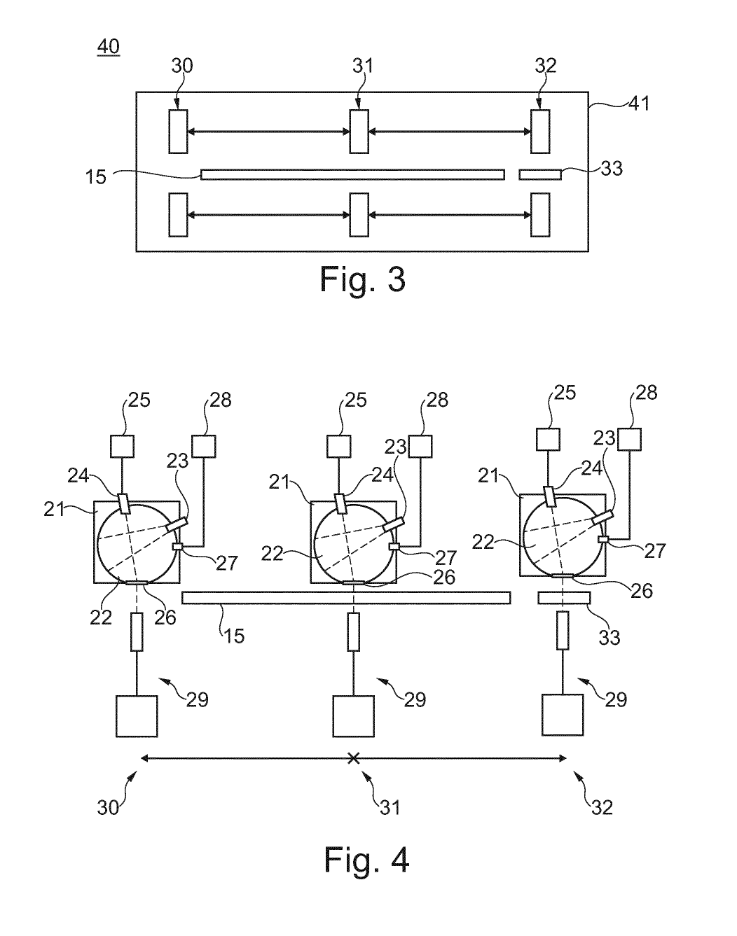

FIGS. 3 and 4 show schematic views of an apparatus 40 for processing of a material on a substrate 15 according to embodiments described herein. The substrate 15 to be processed is placed in a vacuum chamber 41. One or more measuring arrangements according to the embodiments described herein are provided in the vacuum chamber 41.

The measuring arrangement is configured to be moveable in the vacuum chamber 41, particularly between at least three positions 30, 31 and 32.

According to some embodiments, which can be combined with other embodiments described herein, the vacuum chamber 41 can have a flange for connecting a vacuum system, such as a vacuum pump or the like, for evacuating the vacuum chamber 41.

According to some embodiments, which can be combined with other embodiments described herein, the vacuum chamber 41 may be a chamber selected from the group consisting of: a buffer chamber, a heating chamber, a transfer chamber, a cycle-time-adjusting chamber, a deposition chamber, a processing chamber or the like. According to embodiments, which can be combined with other embodiments described herein, the vacuum chamber 41 may be a processing chamber. According to the present disclosure, a “processing chamber” may be understood as a chamber in which a processing device for processing a substrate is arranged. The processing device may be understood as any device used for processing a substrate. For example, the processing device may include a deposition source for depositing a layer onto the substrate. Accordingly, the vacuum chamber or processing chamber including the deposition source may also be referred to as a deposition chamber. The deposition chamber may be a chemical vapor deposition (CVD) chamber or a physical vapor deposition (PVD) chamber.

According to some embodiments, which can be combined with other embodiments described herein, the apparatus may be configured for deposition of material selected from the group consisting of: low index materials, such as SiO2, MgF, mid index material, such as SiN, Al2O3, MN, ITO, IZO, SiOxNy, AlOxNy and high index materials, such as Nb2O5, TiO2, TaO2, or other high index materials.

According to typical embodiments, which can be combined with other embodiments described herein, the apparatus 40 includes at least one load-lock chamber for guiding the substrate 15 in and/or out of the apparatus 40, and particularly in and/or out of the vacuum chamber 41. The at least one load-lock chamber can be configured for changing the interior pressure from atmospheric pressure to vacuum, e.g. to a pressure of 10 mbar or below, or vice versa. According to embodiments, an entry load-lock chamber including an entry port and an exit load-lock chamber including an exit port are provided (not shown).

According to some embodiments of the present disclosure the apparatus 40 includes a transport device configured for moving at least the sphere structure 21 in the vacuum chamber 41. As an example, the transport device is configured for moving at least the sphere structure 21, the first detector and the second detector 29 within the vacuum chamber 41. In some implementations the transport device can include a linear positioning stage. According to some embodiments, which can be combined with other embodiments described herein, the transport device can include an actuator. The actuator can be configured for performing the movement of at least the sphere structure along a trajectory, e.g., a linear trajectory. The actuator may be operated by a source of energy in the form of an electric current, hydraulic fluid pressure or pneumatic pressure converting the energy into motion. According to some embodiments, the actuator can be an electrical motor, a linear motor, a pneumatic actuator, a hydraulic actuator or a piezoelectric actuator.

In typical implementations, the transport device is configured for moving at least the sphere structure 21 to a reflectance calibration position and/or a transmission calibration position. The reflectance calibration position and the transmission calibration may also be referred to as reflectance reference position and transmission reference position, respectively. As an example, the transport device can be configured for moving the sphere structure 21, particularly the sphere structure 21, the first detector and the second detector 29, and more particularly the measuring arrangement between at least three positions 30, 31 and 32. A first position 30 can be the transmission calibration position, a second position 31 can be a measuring position, and a third position 32 can be the reflectance calibration position. The at least three positions 30, 31 and 32 can be free span positions. As an example, the transmission calibration position can be an open position. The measuring position can be a free span position, particularly between two guide rollers. Typically, more than one measuring positions are provided, for instance at least five, and particularly 6, 7, 8, 9 or 10. According to some embodiments, a reflectance reference element 33 can be provided at the reflectance calibration position. The reflectance reference element 33 can provide a known reflection standard. As an example, the reflectance reference element 33 can include or be Silicon (Si).

As an example, a calibration of a transmission measurement and a reflectance measurement can be carried out in a free span position. The sphere structure, the first detector (reflectance sensor) and the second detector (transmission sensor) can be mounted on a moveable linear positioning stage for a synchronous movement. For transmission calibration, the detectors (sensors) are moved to the transmission calibration position for a 100%-calibration. The transmission calibration position can be an open position. For reflection calibration, the detectors (sensors) are moved to the reflectance calibration position, where a known reflection standard (e.g., Si) is provided. Typically, the detectors can be moved to calibration positions with the transport device, which may also be referred to as a drive mechanism. In some embodiments, the measuring positions can be changed, for instance during a production run.

As explained above, according to some embodiments, the apparatus 40 can utilize two reference positions outside the substrate 15. In one position the reflectance can be calibrated by a known reference, for example a calibrated Al-mirror or a polished Si-surface, and the transmittance can be calibrated in the other position with nothing between the sphere structure 21 and the second detector 29. The reflectance and transmission calibration can be repeated periodically in the calibration positions outside the substrate 15 for instance to compensate drift. This may be an aspect in long coating runs lasting for instance several hours.

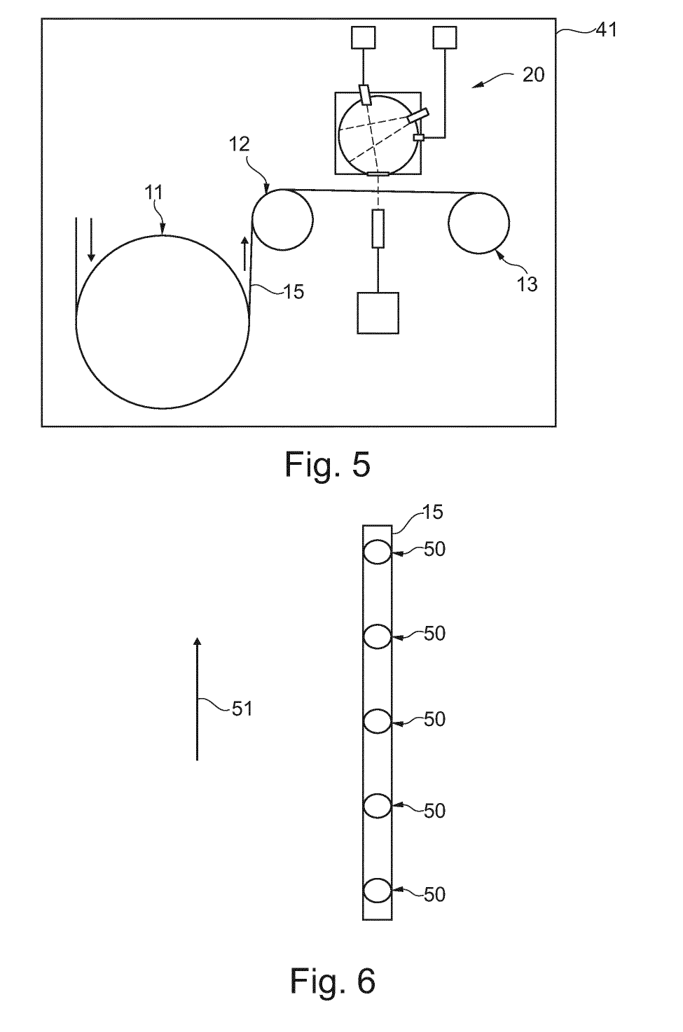

FIG. 5 shows a schematic view of yet another apparatus for processing of a material on a substrate according to embodiments described herein.

The apparatus includes a vacuum chamber 41, a measuring arrangement 20, and a substrate support. The substrate support is configured for supporting the substrate 15. The substrate can be a flexible substrate such as a plastic film, a web, a thin flexible glass or a foil. In some embodiments the substrate support may include at least a first roller 12 and a second roller 13, and may particularly include a coating drum 11, the first roller 12 and the second roller 13. Typically, the substrate 15 is carried and conveyed by the coating drum 11, the first roller 12 and the second roller 13.

According to some embodiments, which can be combined with other embodiments described herein, the first roller 12 and the second roller 13 can be disposed in parallel with a gap formed between the first roller 12 and the second roller 13 for transporting the substrate 15, particularly the flexible substrate. According to typical embodiments, which can be combined with other embodiments described herein, at least the sphere structure is positioned in a region between the first roller 12 and the second roller 13, particularly during measuring the one or more optical properties of the substrate 15 and/or the material processed on the substrate 15. In some embodiments, the measuring arrangement 20, and specifically the sphere structure, the first detector and the second detector are provided in the position between the first roller 12 and the second roller 13. The position between the first roller 12 and the second roller 13 may also be referred to as “free span position”. The position or area between the first roller 12 and the second roller 13 may correspond to a position in or near the gap between first roller 12 and the second roller 13.

The measuring arrangement 20 shown in FIG. 5 can be configured as any one of the measuring arrangements described above with reference to FIGS. 2 to 4.

According to some embodiments, for an inline operation of the measuring arrangement within the vacuum environment, provisions for the measuring arrangement can be provided. As an example, mechanical and/or electronic components of the apparatus, particularly of the measuring arrangement, can be configured to be vacuum-compatible.

According to some embodiments, which can be combined with other embodiments described herein, the measuring arrangement further includes a cooling device (not shown). The cooling device can be configured for cooling at least some of the elements of the measuring arrangement, for instance the sphere structure. A temperature for instance of electronic components of the measuring arrangement can be an aspect that needs to be considered for the stability and accuracy of the measurements. The temperature of the electronic components can be stabilized by the cooling device. According to some embodiments, the cooling device uses water cooling. Water cooling tubes can be lead through flexible hoses. Inside these flexible hoses atmosphere can be provided. This prevents direct water leakage into the vacuum chamber 41, if there is a leakage within the plastic tubes of the water circuit.

According to an aspect of the present disclosure an apparatus for processing of a material on a substrate is provided. The apparatus includes a vacuum chamber, a measuring arrangement configured for measuring at least one of a reflectance and a transmission of the material processed on the substrate, the measuring arrangement including at least one sphere structure located in the vacuum chamber, and a transport device configured for moving at least the sphere structure within the vacuum chamber between a measuring position and at least one calibration position. In typical implementations, the apparatus and particularly the measuring arrangement can be configured as anyone of the measuring arrangements described above.

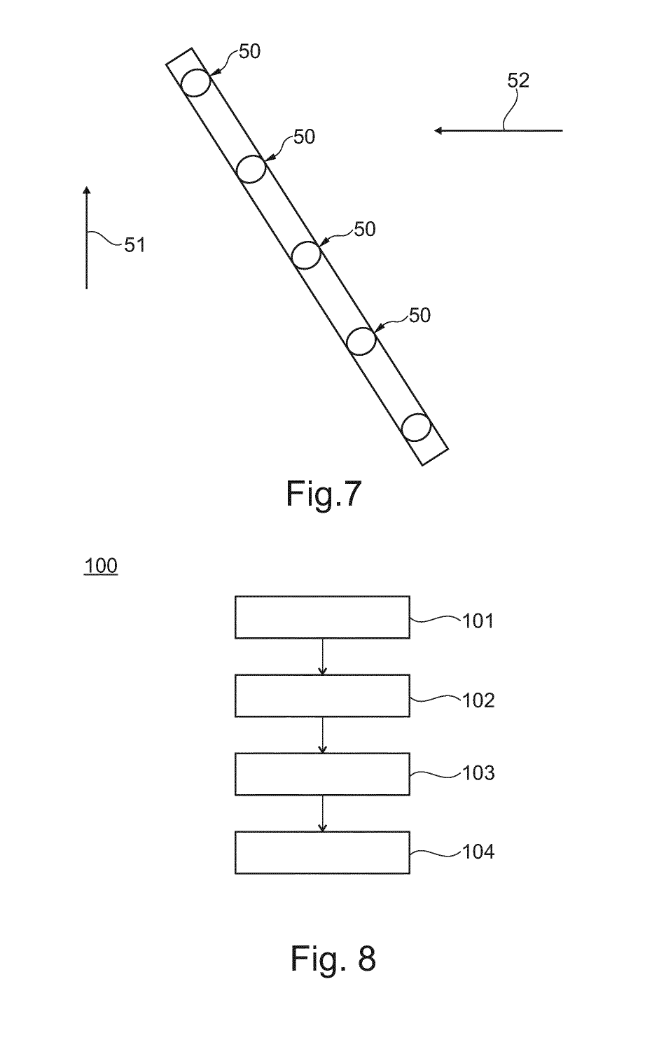

FIGS. 6 and 7 show schematic views of measurement positions for instance for evaluation of a thickness distribution of a material processed or coated on a substrate.

FIGS. 6 and 7 show scanning modes of the measuring arrangement. The measuring arrangement may also be referred to as reflectance/transmission (R/T) head. FIG. 6 shows static measurements for evaluation of a thickness distribution of a material processed or coated on the substrate 15 without a motion of the substrate 15. Scan positions are indicated with reference numeral 50, and a scan direction is indicated with reference numeral 51. The scan positions 50 may correspond to the second positions described above with reference to FIGS. 3 and 4. FIG. 7 shows dynamic measurements for evaluation of a thickness distribution of a material processed or coated on the substrate 15 with a motion of the substrate 15 in a transport direction 52. Scan positions are indicated with reference numeral 50, and a scan direction is indicated with reference numeral 51. The scan positions 50 may correspond to the second positions described above with reference to FIGS. 3 and 4.

FIG. 8 shows a flow chart of a method 100 for measuring one or more optical properties of a substrate and/or a material processed on the substrate by means of an apparatus according to embodiments described herein.

According to some embodiments, which can be combined with other embodiments described herein, the method 100 for measuring one or more optical properties of a substrate and/or a material processed on a substrate by means of a processing apparatus in provided. The processing apparatus includes a vacuum chamber and can be configured as anyone of the apparatuses described above. The method includes measuring the one or more optical properties using a measuring arrangement having at least one sphere structure located in the vacuum chamber.

In some embodiments, the method 100 may include moving at least the sphere structure to a first calibration position in the vacuum chamber, particularly to a reflectance calibration position (block 101), and calibrating (102) the measuring arrangement. In typical implementations the method 100 may include moving at least the sphere structure to a second calibration position in the vacuum chamber, particularly to a transmission calibration position (block 103), and calibrating (104) the measuring arrangement.

According to some embodiments, which can be combined with other embodiments described herein, at least one of the calibration at the first calibration position (blocks 101 and 102) and the calibration at the second calibration position (blocks 103 and 104) are periodically or a-periodically repeated. As an example, the calibration can be repeated in predetermined time intervals, after a processing cycle, during a processing cycle, and the like. The reflectance and transmission calibration can be repeated periodically in the calibration positions for instance to compensate drift. This may be an aspect in long coating runs lasting for instance several hours.

According to embodiments described herein, the method for measuring one or more optical properties of the substrate and/or the material processed on a substrate by means of a processing apparatus can be conducted by means of computer programs, software, computer software products and the interrelated controllers, which can have a CPU, a memory, a user interface, and input and output means being in communication with the corresponding components of the apparatus for processing a large area substrate.

The present disclosure uses sphere structures within a vacuum chamber for reflectance and/or transmission measurements for instance in a free span position of a substrate such as a plastic film between two rollers. According to some embodiments, reflectance and transmission measurements can be performed at the same position. Even if the surface of the film is not flat, the reflected light is almost completely collected in the sphere structure. According to some embodiments, to allow measurements on any selected position along the substrate width, the measuring arrangement of the apparatus can be installed on a linear positioning stage for instance driven by a motor. In combination with a detector for transmittance the apparatus according to embodiments described herein allows reflection and transmission measurements at pre-defined positions of the material processed on the substrate, for instance a coated film. Particularly the reflectance measurement is insensitive to changes (wrinkles) of the substrate plane (e.g., +/−5 mm).

As described above, the apparatus of the present disclosure allows a simultaneous measurement of a reflection and a transmission at user defined positions for instance during processing the substrate. Particularly, transmission and reflection measurements can be performed at the same position, for instance with only one linear positioning stage having for instance two coupled axes. Using the sphere structure provides an improved reflectance measurement accuracy. Particularly, no reflectance offset by interfering reflectance of a blackened roller as described above with reference to FIG. 1 occurs. The apparatus can provide a reduced time for machine setup during process installation, wherein a uniformity can be measured inline or in-situ without cutting samples for measurement. A reduced process installation time can be achieved. For instance, a reduction of the process installation time of about 30%-50% is possible. Reliable spectral data obtainable with the measuring arrangement allow recalculation of multilayer systems for further evaluation of layer thickness values. The apparatus can for instance be used for inspection of optical layer systems, such as antireflection, invisible ITO, window films, and the like. An optical quality control for customer over a total web width can be possible. According to some embodiments, the apparatus and particularly the measuring arrangement has electromagnetic interference (EMI) compatibility and can tolerate strong electrical fields for instance induced by sputter deposition sources (DC, MF, RF).

While the foregoing is directed to embodiments of the disclosure, other and further embodiments of the disclosure may be devised without departing from the basic scope thereof, and the scope thereof is determined by the claims that follow.

1. An apparatus for processing of a material on a substrate, comprising:
a vacuum chamber; and
a measuring arrangement configured for measuring one or more optical properties of the substrate and/or the material on the substrate, the measuring arrangement comprising at least one sphere structure located in the vacuum chamber.

2. The apparatus of claim 1, wherein the one or more optical properties are selected from the group consisting of: a reflectance and a transmission.

3. The apparatus of claim 1, wherein the sphere structure is an integrating sphere.

4. The apparatus of claim 1, further including a substrate support in the vacuum chamber, wherein the substrate support is configured for supporting the substrate.

5. The apparatus of claim 4, wherein the substrate support includes a first roller and a second roller disposed parallel with a gap formed between the first roller and the second roller for transporting the substrate.

6. The apparatus of claim 5, wherein the sphere structure is positioned in a region between the first roller and the second roller during the measuring one or more optical properties of the substrate and/or the material on the substrate.

7. The apparatus of claim 1, wherein the measuring arrangement includes a light source at the sphere structure and a first detector at the sphere structure for a reflectance measurement of the substrate and/or the material on the substrate.

8. The apparatus of claim 1, wherein the measuring arrangement includes a light source at the sphere structure and a second detector for a transmission measurement of the substrate and/or the material on the substrate.

9. The apparatus of claim 1, further including a transport device configured for moving at least the sphere structure within the vacuum chamber.

10. The apparatus of claim 9, wherein the transport device is configured for moving at least the sphere structure to a reflectance calibration position and/or a transmission calibration position.

11. The apparatus of claim 1, wherein the measuring arrangement further includes a cooling device.

12. A method for measuring one or more optical properties of a substrate and/or a material on the substrate by means of a processing apparatus, wherein the processing apparatus comprises a vacuum chamber, the method comprising:
measuring the one or more optical properties using a measuring arrangement having at least one sphere structure provided in the vacuum chamber.

13. The method of claim 12, further including:
moving at least the sphere structure to a first calibration position in the vacuum chamber to a reflectance calibration position, and calibrating the measuring arrangement; or
moving at least the sphere structure to a second calibration position in the vacuum chamber, particularly to a transmission calibration position, and calibrating the measuring arrangement.

14. The method of claim 13, wherein the calibrating at the first calibration position and the calibrating at the second calibration position are periodically or a-periodically repeated.

15. An apparatus for processing of a material on a substrate, comprising:
a vacuum chamber;
a measuring arrangement including at least one sphere structure in the vacuum chamber, wherein the measuring arrangement is configured for measuring at least one of a reflectance and a transmission of the substrate and/or the material processed on the substrate; and
a transport device configured for moving at least the sphere structure within the vacuum chamber between a measuring position and at least one calibration position.

16. The apparatus of claim 1, further including a substrate support in the vacuum chamber, wherein the substrate support is configured for supporting the substrate, and wherein the substrate is a flexible substrate.

17. The apparatus of claim 5, wherein the substrate support includes a first roller and a second roller disposed parallel with a gap formed between the first roller and the second roller for transporting the substrate.

18. The apparatus of claim 7, wherein the sphere structure is positioned in a region between the first roller and the second roller during measuring the one or more optical properties of the substrate and/or the material on the substrate.

19. The apparatus of claim 12, wherein the transport device is configured for moving at least the sphere structure within the vacuum chamber.

20. The apparatus of claim 1, wherein the measuring arrangement is configured for an inline operation within the vacuum environment.
